(19) United States
(12) Patent Application Publication
(10) Pub. No.: US 2025/0069846 A1
(43) Pub. Date: Feb. 27, 2025

(54) SENSOR DEVICE AND SYSTEM USING THE SAME

(71) Applicant: SAMSUNG ELECTRONICS CO., LTD., Suwon-si (KR)

(72) Inventors: Solhee IN, Suwon-si (KR); Dohyung Kim, Suwon-si (KR); Sungsoo Kim, Suwon-si (KR); Jaesup Lee, Suwon-si (KR); Byungwook Jung, Suwon-si (KR)

(73) Assignee: SAMSUNG ELECTRONICS CO., LTD., Suwon-si (KR)

(21) Appl. No.: 18/584,633

(22) Filed: Feb. 22, 2024

(30) Foreign Application Priority Data
Aug. 21, 2023 (KR) 10-2023-0109062

(51) Int. Cl. H01J 37/244; H01J 37/32; H02J 50/20; H02J 50/40; H02J 50/90

(52) U.S. Cl. CPC H01J 37/244; H01J 37/32935; H02J 50/20; H02J 50/40; H02J 50/90

(57) ABSTRACT

A system includes a radio frequency (RF) device outputting an RF signal; and at least one sensor device generating a power supply voltage using the RF signal output from the RF device, and operating by the power supply voltage, wherein the sensor device includes a case; a plurality of detectors disposed in the case, and collecting environmental data of a space in which the RF device and the sensor device are input, to generate detection data; a battery supplying a power supply voltage necessary for operation of the plurality of detectors; and a charger charging the battery, wherein the charger includes an antenna installed in the case and receiving RF power from an external source, an RF-DC converter converting an alternating current voltage corresponding to the RF power into a direct current voltage, a matching circuit connected between the antenna and the RF-DC converter, and a DC-DC converter adjusting a level of the direct current voltage and charging the battery.

### CROSS-REFERENCE TO RELATED APPLICATION

This application claims priority to Korean Patent Application No. 10-2023-0109062 filed on Aug. 21, 2023 in the Korean Intellectual Property Office, the disclosure of which is incorporated herein by reference in its entirety.

### BACKGROUND

### 1. Field

The disclosure relates to a sensor device and a system using the same.

### 2. Description of Related Art

In a semiconductor processing device that performs a semiconductor process to be placed on a substrate, such as a wafer or the like, and in a system in which the semiconductor processing device is disposed, various pieces of data may be collected to maintain a stable yield of the semiconductor process. For example, yield of the semiconductor process may be stably managed by acquiring detection data indicating characteristics of plasma generated in a space in the semiconductor processing device, or acquiring detection data indicating environment of a space in which a system including semiconductor processing devices are installed, and, based thereon, controlling the semiconductor processing device, the system, or the like. Detection data, as above, may be acquired by a sensor device that may be input into the semiconductor processing device or may be mounted in a space in which the system is installed, and various methods have been proposed to implement an efficient sensor device.

### SUMMARY

to the disclosure provides a sensor device that may generate power required for operation using an RF signal emitted by an external RF device, and a system using the same.

According to an aspect of the disclosure a system includes: a radio frequency (RF) device configured to output an RF signal; and at least one sensor device configured to generate a power supply voltage using the RF signal, wherein the at least one sensor device is configured to operate on the power supply voltage, wherein the at least one sensor device includes: a case; a plurality of detectors disposed in the case, wherein the plurality of detectors are configured to operate on the power supply voltage, to collect environmental data of a space in which the at least one sensor device is inserted, and to generate detection data; a battery configured to supply the power supply voltage; and a charger configured to charge the battery, and wherein the charger includes an antenna disposed in the case and configured to receive RF power from an external source, an RF-DC converter configured to convert an alternating current voltage corresponding to the RF power into a direct current voltage, a matching circuit connected between the antenna and the RF-DC converter, and a DC-DC converter configured to adjust a level of the direct current voltage and to charge the battery.

According to an aspect of the disclosure, a sensor device includes: a case; an antenna disposed in the case and configured to receive a radio frequency (RF) signal transmitted by an RF device; a matching circuit connected to the antenna and configured to output an alternating current voltage; an RF-DC converter configured to convert the alternating current voltage into a direct current voltage; a DC-DC converter configured to adjust a level of the direct current voltage to generate a power supply voltage; a plurality of detectors configured to: operate using the power supply voltage, collect environmental data in a space outside the case, and generate detection data; and a transmitter configured to output a wireless signal configured to be recognized by the RF device.

According to an aspect of the disclosure, a system includes: a plurality of radio frequency (RF) devices, each installed in a different position and each transmitting an RF signal; and a plurality of sensor devices disposed in a space in which the plurality of RF devices are installed, wherein each of the plurality of sensor devices is configured to: generate a power supply voltage using the RF signal transmitted by at least one of the plurality of RF devices, and operate based on the power supply voltage, and wherein each of the plurality of sensor devices includes a transmitter configured to transmit a wireless signal configured to be recognized by each of the plurality of RF devices.

### BRIEF DESCRIPTION OF THE DRAWINGS

The above and other aspects, features, and advantages of certain embodiments of the present disclosure will be more clearly understood from the following detailed description taken in conjunction with the accompanying drawings, in which:

FIGS. 1 and 2 are views illustrating systems using a sensor device according to an embodiment;

FIG. 3 is a view illustrating processing devices according to an embodiment;

FIG. 4 is a view illustrating a block diagram representing a sensor device according to an embodiment;

FIGS. 5 and 6 are views illustrating circuits included in a sensor device according to an embodiment;

FIGS. 7 and 8 are views illustrating block diagrams of sensor devices according to an embodiment;

FIG. 9 is a view illustrating a block diagram of an RF device included in a system according to an embodiment;

FIGS. 10, 11 and 12 are block diagrams illustrating operation of a system according to an embodiment;

FIG. 13 is a view illustrating an operation of a system according to an embodiment;

FIGS. 14 and 15 are views illustrating a sensor device according to an embodiment; and

FIG. 16 is a view illustrating a semiconductor processing device into which a different sensor device may be inserted according to an embodiment.

### DETAILED DESCRIPTION

Hereinafter, one or more embodiments of the present disclosure will be described with reference to the attached drawings.

In the following description, like reference numerals refer to like elements throughout the specification.

Terms such as “unit”, “module”, “member”, and “block” may be embodied as hardware or software. According to embodiments, a plurality of “unit”, “module”, “member”, and “block” may be implemented as a single component or a single “unit”, “module”, “member”, and “block” may include a plurality of components.

It will be understood that when an element is referred to as being “connected” with or to another element, it can be directly or indirectly connected to the other element, wherein indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expression “at least one of a, b or c” indicates “only a,” “only b,” “only c,” “both a and b,” “both a and c,” “both b and c,” or “all of a, b, and c.”

It will be understood that, although the terms “first”, “second”, “third”, etc., may be used herein to describe various elements, the disclosure should not be limited by these terms. These terms are only used to distinguish one element from another element.

As used herein, the singular forms “a,” “an” and “the” are intended to include the plural forms as well, unless the context clearly indicates otherwise.

An identification code may be used for the convenience of the description but is not intended to illustrate the order of each step or operation. Each step or operation may be implemented in an order different from the illustrated order unless the context clearly indicates otherwise.

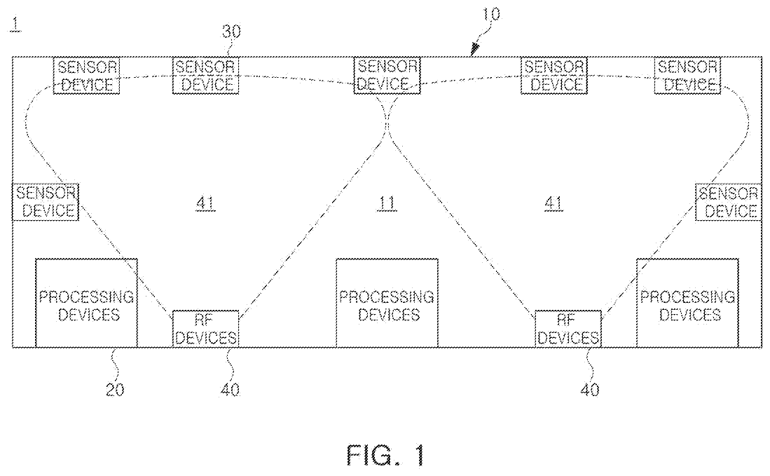

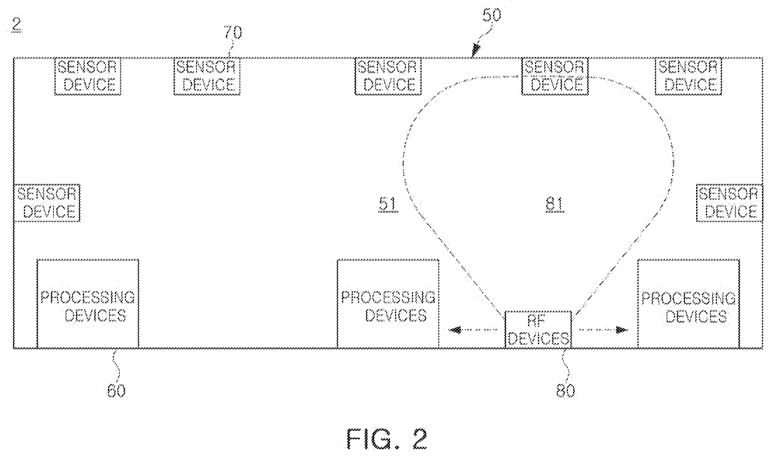

FIGS. 1 and 2 are views illustrating systems using a sensor device according to an embodiment.

Referring to FIG. 1, a system 1, according to an embodiment, may be a production line performing a semiconductor process, and may be implemented in a building 10. In an embodiment illustrated in FIG. 1, the system 1 may include a plurality of processing devices 20, a plurality of sensor devices 30, and a plurality of RF devices 40, installed in the building 10.

Each of the plurality of processing devices 20 may include at least one semiconductor process device performing a semiconductor process such as a deposition process, a photolithography process, an etching process, or the like. Each of the plurality of processing devices 20 may include a transfer facility for transferring a wafer or the like, for example, a wafer transfer device receiving a wafer or the like from an overhead transport (OHT) and transferring the same to semiconductor processing devices. The wafer may be transferred between the plurality of processing devices 20 by the transfer facility while being mounted on a transfer container such as a front open unified pod (FOUP) or the like.

The plurality of sensor devices 30 may be installed in an internal space 11 of the building 10 in which the system 1 may be implemented, and therefore the plurality of sensor devices 30 may be installed in the internal space 11 of the building 10 in which the system 1 is installed in the internal space 11, such as the plurality of processing devices 20. For example, the internal space 11 of the building 10 in which the plurality of processing devices 20 are installed may be maintained in a clean room environment. To maintain the internal space 11 of the building 10 in the clean room environment, a filter, an air circulator, or the like may be installed in the building 10.

The plurality of sensor devices 30 may collect environmental data of the internal space 11 of the building 10, and may generate detection data. For example, the plurality of sensor devices 30 may generate detection data by monitoring the environmental data such as an amount of dust present in the internal space 11, a temperature of the internal space 11, an atmospheric pressure of the internal space 11, humidity of the internal space 11, or the like. Depending on an embodiment, the plurality of sensor devices 30 may operate as a type of an internet-of-things (IoT) device.

The detection data generated by the plurality of sensor devices 30 may be transferred to control equipment installed inside or outside the building 10 in a wired or wireless communication manner. The control equipment may be equipment controlling the plurality of processing devices 20, and the filter, the air circulator, or the like, installed in the building 10. The control equipment may maintain the internal space 11 of the building 10 as a clean room environment by controlling the filter, the air circulator, or the like, based on the detection data transmitted by the plurality of sensor devices 30, and may control operations of the plurality of processing devices 20.

Each sensor device of the plurality of sensor devices 30 may include a plurality of detectors monitoring environmental data and generating detection data, as illustrated above. In order for the plurality of detectors to monitor the environmental data, a predetermined power supply voltage should be supplied, and in an embodiment, each of the plurality of sensor devices 30 may produce a power supply voltage using an RF signal 41 output from the RF devices 40. For example, each of the plurality of sensor devices 30 may convert the RF signal 41 into an alternating current voltage, and may convert the alternating current voltage back into a direct current voltage to produce a power supply voltage required for the operation of the plurality of detectors.

When the plurality of RF devices 40 are installed in an appropriate position in the internal space 11, the RF signal 41 output from each of the plurality of RF devices 40 may entirely cover the internal space 11. Therefore, each of the plurality of sensor devices 30 may be freely installed in a desired position without need to connect each of the plurality of sensor devices 30, and the environment of the internal space 11 may be maintained and managed in an optimized state using the detection data generated by the plurality of sensor devices 30. In an embodiment, the RF devices 40 may be installed outside of the internal space 11 so long as they are configured to provide RF coverage of the internal space 11.

Each of the plurality of sensor devices 30 may be freely installed as long as it is within coverage of the RF signal 41 output by at least one of the plurality of RF devices 40. In addition, since the plurality of sensor devices 30 may be implemented with a small capacity battery or without a battery structure, the size of each of the plurality of sensor devices 30 may be reduced to decrease impact on placement of the processing devices 20 included in the system 1.

Next, referring to FIG. 2, a system 2 according to an embodiment may include a plurality of processing devices 60, a plurality of sensor devices 70, and an RF device 80, arranged in an internal space 51 of a building 50. A configuration of the plurality of processing devices 60 and the plurality of sensor devices 70 may be similar to that previously described with reference to FIG. 1. Additionally, the internal space 51 of the building 50 may be maintained as a clean room environment for a production line of a semiconductor.

In an embodiment illustrated in FIG. 2, the RF device 80 may emit an RF signal 81 while moving in the internal space 51. When the RF device 80 moves to an adjacent position and emits the RF signal 81, the plurality of sensor devices 70 may receive the RF signal 81 and may produce a power supply voltage.

Each of the plurality of sensor devices 70 may include a battery that may be charged by the power supply voltage generated from the RF signal 81 such that the plurality of sensor devices 70 may operate even in a situation outside coverage of the RF signal 81 emitted by the RF device 80. Therefore, even in a situation in which the RF signal 81 may not be directly received, each of the plurality of sensor devices 70 may monitor environmental data of the internal space 51 using the power supply voltage supplied by the battery.

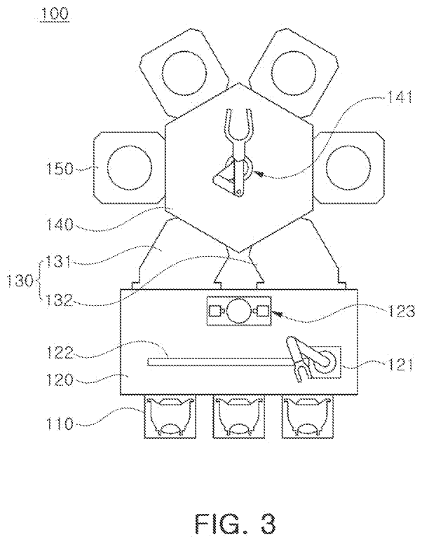

FIG. 3 is a view illustrating processing devices according to an embodiment.

Referring to FIG. 3, processing devices 100 according to an embodiment may include a wafer transfer device 120, a load lock chamber 130, a transfer chamber 140, a plurality of semiconductor processing devices 150, or the like. For example, the wafer transfer device 120 may receive a wafer through a container such as an FOUP 110 or the like in a production line in which one or more processing devices 100 are disposed. The wafer transfer device 120 may transfer the wafer received through the FOUP 110 to the load lock chamber 130, or may receive a wafer on which a semiconductor process has been completed in one or more of the semiconductor processing devices 150 from the load lock chamber 130, and may store the same in the FOUP 110.

The wafer transfer device 120 may include a wafer transfer robot 121 having an arm capable of holding the wafer, a rail unit 122 for moving the wafer transfer robot 121, an aligner 123 aligning the wafer, and the like. In an operation of transferring the wafer from the FOUP 110 to the load lock chamber 130, the wafer transfer robot 121 may draw the wafer stored in the FOUP 110 out, and may place the same on the aligner 123. The aligner 123 may rotate the wafer to align the same in a predetermined direction. When wafer alignment is completed in the aligner 123, the wafer transfer robot 121 may take the wafer out of the aligner 123, and may transfer the same to the load lock chamber 130.

The load lock chamber 130 may be connected to the wafer transfer device 120, and may include a loading chamber 131 in which wafers inserted into the semiconductor processing device 150 for the semiconductor process temporarily stay, an unloading chamber 132 in which the process is completed and wafers output from the semiconductor processing device 150 temporarily stay, and the like. When the wafer aligned in the aligner 123 is inserted into the loading chamber 131, an internal space of the loading chamber 131 may be depressurized to prevent an external contaminant from entering.

The load lock chamber 130 may be connected to the transfer chamber 140, and the plurality of semiconductor processing devices 150 may be arranged around the transfer chamber 140. A wafer transfer robot 141 may be disposed inside the transfer chamber 140 to transfer the wafer between the load lock chamber 130 and the plurality of semiconductor processing devices 150. The wafer transfer robot 121 of the wafer transfer device 120 may be referred to as a first wafer transfer robot, and the wafer transfer robot 141 of the transfer chamber 140 may be referred to as a second wafer transfer robot.

Each of the plurality of semiconductor processing devices 150 may perform the semiconductor process on the wafer. For example, the semiconductor process performed by the plurality of semiconductor processing devices 150 may include a deposition process, an etching process, an exposure process, an annealing process, a polishing process, an ion implantation process, or the like.

To perform at least a portion of the above-mentioned semiconductor processes, plasma may be formed inside at least one of the plurality of semiconductor processing devices 150. The plasma may be formed on a wafer, a mask, a display mother substrate, or the like, which are objects of semiconductor processing, and a yield of the process may vary depending on how the plasma is formed. Therefore, before actually performing the semiconductor process in the semiconductor processing devices 150, forming the plasma and analyzing characteristics thereof may first be performed.

In an embodiment, a sensor device having a shape, as that of a process object that may be inserted into the semiconductor processing devices 150, for example, a wafer, a mask, a display mother substrate, or the like, may be used to analyze the characteristics of the plasma formed in the semiconductor processing devices 150. For example, the sensor device may include a plurality of detectors collecting environmental data inside the semiconductor processing devices 150 in which the plasma is generated to generate detection data, a battery supplying a power supply voltage necessary for operation of the plurality of detectors, a charger for charging the battery, and the like.

For example, the plurality of detectors may generate detection data such as a temperature of the plasma, vibration, intensity of light emitted from the plasma, or the like. The detection data generated by the plurality of detectors in the sensor device may be transmitted to external control equipment. The control equipment may be a device such as a server that controls and manages the production line including the processing devices 100. The control equipment may improve yield of the semiconductor process by analyzing density, temperature distribution, or the like of the plasma using the detection data, and controlling the semiconductor processing devices 150 based thereon.

The battery of the sensor device may be charged by the charger before being inserted into the plurality of semiconductor processing devices 150. For example, in a manner similar to a wafer or the like, the sensor device may be stored in the FOUP 110 and transferred to the processing devices 100, and the battery may be charged by the charger while the sensor device is stored in the FOUP 110.

As previously described with reference to FIGS. 1 and 2, an RF device transmitting an RF signal may be installed in an internal space of the production line in which the processing devices 100 are installed. The charger of the sensor device may include a circuit that generates a direct current voltage for charging the battery using the RF signal transmitted by the RF device. For example, the charger may include an antenna, an RF-DC converter, a DC-DC converter, or the like.

For example, the charger may charge the battery using the RF signal while the FOUP 110 containing the sensor device is seated on the processing devices 100. Considering that the internal environment of each of the semiconductor processing devices 150 may be an extreme environment with a high temperature and a low pressure, a low capacity battery may be employed in the sensor device, and thus a time period required for the charger to charge the battery may be set short.

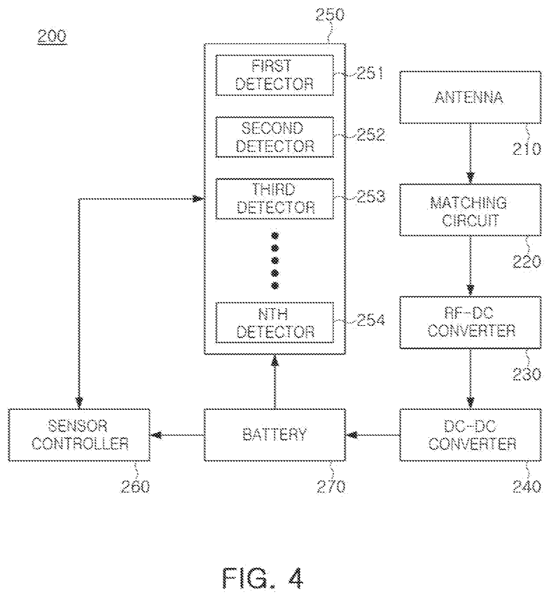

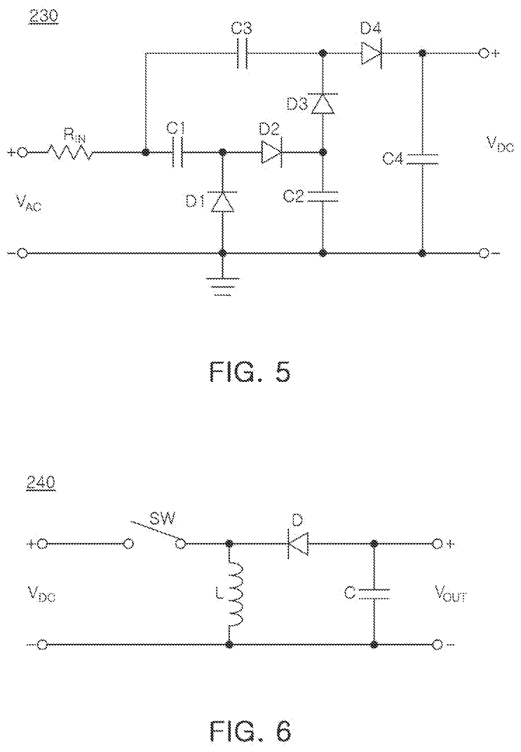

FIG. 4 is a view illustrating a block diagram representing a sensor device according to an embodiment. FIGS. 5 and 6 are views illustrating circuits included in a sensor device according to an embodiment.

Referring to FIG. 4, a sensor device 200 according to an embodiment may include an antenna 210, a matching circuit 220, an RF-DC converter 230, a DC-DC converter 240, a plurality of detectors 250 (e.g., first detector 251, second detector 252, third detector 253, and nth detector 254), a sensor controller 260, a battery 270, and the like. The antenna 210, the matching circuit 220, the RF-DC converter 230, the DC-DC converter 240, the plurality of detectors 250, the sensor controller 260, and the battery 270 may be stored in a case of the sensor device 200.

The antenna 210, the matching circuit 220, the RF-DC converter 230, and the DC-DC converter 240 may provide a charger for charging the battery 270. Depending on an embodiment, at least one of the matching circuit 220 or the DC-DC converter 240 may be omitted. The antenna 210 may be implemented as a patch antenna, a dipole antenna, a monopole antenna, or the like. For example, depending on a type of antenna 210, a position in which the antenna 210 is disposed in the case of the sensor device 200 may vary.

For example, when the antenna 210 is a dipole antenna or a monopole antenna, the antenna 210 may be disposed adjacent to an edge of the case. When the antenna 210 is a patch antenna, the antenna 210 may be freely disposed in various positions in the case, and, in an embodiment, may be disposed in a position overlapping a center of the case.

The matching circuit 220 may include an inductor element, a capacitor element, or the like. The antenna 210 may receive an RF signal emitted by an external RF device, and the matching circuit 220 may output an alternating current voltage. As an example, matching circuit 220 may provide frequency impedance matching in a specific frequency band. The alternating current voltage output by the matching circuit 220 may be converted to a direct current voltage in the RF-DC converter 230.

The RF-DC converter 230 may be implemented as a rectifier circuit, a charge pump, or the like. Referring to FIG. 5 illustrating an example circuit of an RF-DC converter 230, the RF-DC converter 230 may include a Dixon charge pump circuit. In an embodiment illustrated in FIG. 5, the RF-DC converter 230 may include a plurality of capacitor elements C1 to C4, a plurality of diodes D1 to D4, a resistor element R_{IN}, or the like, and may convert an alternating current voltage (V_{AC}) received from a matching circuit 220 to a direct current voltage (V_{DC}), and may output the same. The charge pump circuit for implementing the RF-DC converter 230 is not necessarily limited to that illustrated in FIG. 5, and the RF-DC converter 230 may be implemented as various circuits capable of converting the alternating current voltage (V_{AC}) to the direct current voltage (V_{DC}).

The direct current voltage (V_{DC}) output by the RF-DC converter 230 may be input to a DC-DC converter 240. The DC-DC converter 240 may increase or decrease a level of the direct current voltage (V_{DC}), and may output the same, and a battery 270 may be charged by voltage output by the DC-DC converter 240. For example, the DC-DC converter 240 may adjust the level of the direct current voltage (V_{DC}) to an appropriate level of voltage for charging the battery 270.

The DC-DC converter 240 may be implemented in various topologies such as a buck converter, a boost converter, a buck-boost converter, or the like. As an example, FIG. 6 is a view illustrating an example circuit that may provide a DC-DC converter 240, and in an embodiment illustrated in FIG. 6, the DC-DC converter 240 may include a buck-boost converter. Referring to FIG. 6, the DC-DC converter 240 may include a switch element SW, an inductor element L, a diode D, a capacitor element C, or the like.

When receiving a direct current voltage (V_{DC}) from an RF-DC converter 230, the switch element SW of the DC-DC converter 240 may repeatly turn-on and turn-off (i.e., close and open) to generate an output voltage (V_{OUT}). For example, energy may be charged to the inductor element L by the direct current voltage (V_{DC}) while the switch element SW is turned on. When the switch element SW is turned off, the output voltage (V_{OUT}) may be supplied by the energy charged in the inductor element L. A switching speed and a duty ratio of the switch element SW included in the DC-DC converter 240 may be controlled to adjust a level of the output voltage (V_{OUT}).

A charged battery 270 may supply a power supply voltage necessary for operations of a plurality of detectors 250 and a sensor controller 260. For example, each of the plurality of detectors 250 may include at least one sensor capable of detecting environmental data such as a temperature, a dust concentration, a pressure, intensity of light emitted from a surrounding space, or the like in a sensor device 200. Depending on an embodiment, at least a portion of a plurality of detectors 250 included in a single sensor device 200 may detect different environmental data.

For example, a first detector 251 may detect a temperature, a second detector 252 may detect an atmospheric pressure, and a third detector 253 may detect a dust concentration. The sensor controller 260 may control the plurality of detectors 250 such that each of the plurality of detectors 250 collects environmental data and generates detection data, and may receive and process the detection data from the plurality of detectors 250.

Each of the plurality of detectors 250 may collect environmental data at each predetermined sensing cycle, and may generate detection data. For example, a sensing cycle of each of the plurality of detectors 250 may be longer than a time period required for an antenna 210, a matching circuit 220, an RF-DC converter 230, and a DC-DC converter 240 to generate a power supply voltage using an RF signal. In an embodiment, the sensing period of each of the plurality of detectors 250 may be about 1 second, and the time period required to generate the power supply voltage from the RF signal may be several ms or less.

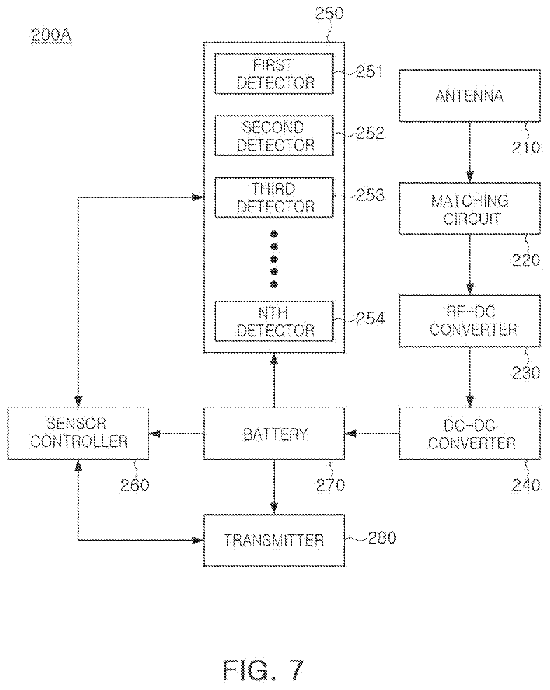

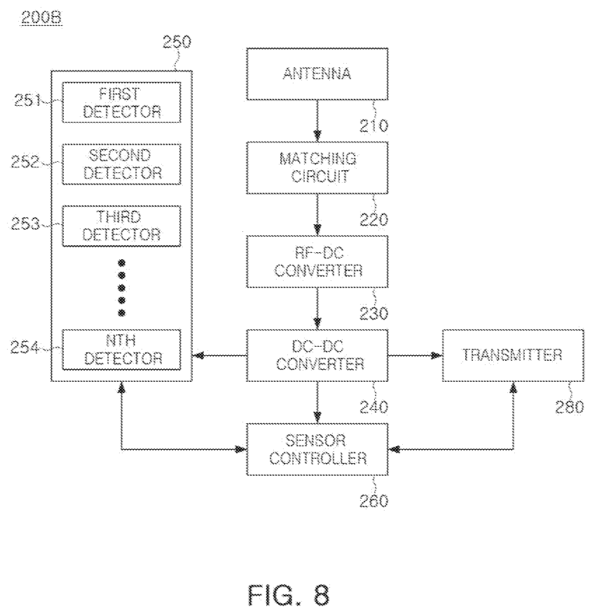

FIGS. 7 and 8 are views illustrating block diagrams of sensor devices according to an embodiment.

First, referring to FIG. 7, a sensor device 200A according to an embodiment may include an antenna 210, a matching circuit 220, an RF-DC converter 230, a DC-DC converter 240, a plurality of detectors 250, a sensor controller 260, a battery 270, a transmitter 280, and the like. Configurations and operations of the antenna 210, the matching circuit 220, the RF-DC converter 230, the DC-DC converter 240, the plurality of detectors 250 (e.g., first detector 251, second detector 252, third detector 253, and nth detector 254), the sensor controller 260, and the battery 270 may be similar to those previously described with reference to FIG. 4.

The transmitter 280 may operate by receiving a power supply voltage from the battery 270. The transmitter 280 may transmit a wireless signal externally that may be recognized by an external RF device. For example, the wireless signal transmitted by the transmitter 280 may be a signal containing information data that allows the RF devices to reinterpret position data of a subject in which emits the wireless signal, and may be a beacon signal. For example, the transmitter 280 may transmit a pilot signal, and the RF device may determine a position of the sensor device 200A, a distance to the sensor device 200A, or the like, based on the wireless signal, and may adjust at least one of a direction in which an RF signal is transmitted or intensity of the RF signal, based thereon. Depending on the wireless signal transmitted by the transmitter 280, the transmitter 280 may transmit the wireless signal through the antenna 210.

In an embodiment, the RF device may determine the distance to the sensor device 200A, the position of the sensor device 200A, or the like, using a time reversal method. For example, the RF device may use a time reversal method to complex conjugate a phase and/or an amplitude of the wireless signal. The RF device may perform a beamforming operation to adjust a transmission direction or the like of the RF signal, and the RF signal may be transmitted with optimal intensity and direction toward the sensor device 200A. Therefore, efficiency of charging the battery 270 using the RF signal may be improved.

The transmitter 280 may also be used to transmit a data signal to external control equipment by the sensor controller 260. For example, the sensor controller 260 may transmit a data signal containing the detection data generated by the plurality of detectors 250 to the control equipment through the transmitter 280. Depending on an embodiment, the control equipment may be implemented as one equipment with the RF device, or may be implemented as separate equipment.

Next, referring to FIG. 8, a sensor device 200B according to an embodiment may include an antenna 210, a matching circuit 220, an RF-DC converter 230, a DC-DC converter 240, a plurality of detectors 250 (e.g., detectors 251 to 254), a sensor controller 260, a transmitter 280, and the like. In an embodiment illustrated in FIG. 8, the sensor device 200B may not include a battery. Instead, a voltage output by the DC-DC converter 240 may be directly supplied as a power supply voltage of the plurality of detectors 250, the sensor controller 260, and the transmitter 280.

For example, in an embodiment illustrated in FIG. 8, a power supply voltage required for operation of each of the plurality of detectors 250, the sensor controller 260, and the transmitter 280 may be generated and supplied in real time. An RF signal transmitted by an external RF device may be converted into an alternating current voltage at the antenna 210, and the RF-DC converter 230 may convert the alternating current voltage output by the matching circuit 220 into a direct current voltage.

The DC-DC converter 240 may adjust a level of the direct current voltage output by the RF-DC converter 230 onto a level suitable for the sensor controller 260, the plurality of detectors 250, and the transmitter 280, to generate the power supply voltage. Depending on an embodiment, at least a portion of the sensor controller 260, the plurality of detectors 250, and the transmitter 280 may require different levels of power supply voltage, and in this case, the DC-DC converter 240 may include a plurality of circuits that differently adjust the level of the direct current voltage output by the RF-DC converter 230.

The sensor device 200B according to an embodiment illustrated in FIG. 8 may be used to analyze internal environment of a production line in which processing devices and an RF device are installed. For example, the sensor device 200B may be adopted, as the sensor devices 30 and 70 according to embodiments described with reference to FIGS. 1 and 2. In this case, the sensor device 200B may be installed in a space in which a production line is implemented, and may receive the RF signal transmitted by the RF device all the time or at regular intervals. Therefore, the plurality of detectors 250, the sensor controller 260, the transmitter 280, or the like may be operated by the power supply voltage output by the DC-DC converter 240 without a separate battery.

As illustrated in FIG. 8, the sensor device 200B may be implemented, without a battery, to improve stability and versatility of the sensor device 200B. For example, when the sensor device 200B should be directly inserted into semiconductor processing devices, the sensor device 200B may be implemented, without a battery, to operate the sensor device 200B stably even in an environment maintained at a relatively low atmospheric pressure.

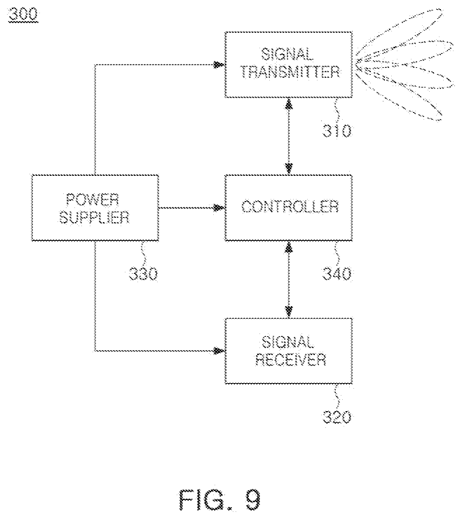

FIG. 9 is a view illustrating a block diagram of an RF device included in a system according to an embodiment.

Referring to FIG. 9, an RF device 300 according to an embodiment may include a signal transmitter 310, a signal receiver 320, a power supplier 330, a controller 340, and the like. The signal transmitter 310 may transmit an RF signal externally. For example, intensity and frequency of the RF signal transmitted by the signal transmitter 310, a transmission direction of the RF signal, or the like may be controlled by the controller 340.

The signal receiver 320 may receive a wireless signal or the like output from a different external device. For example, the signal receiver 320 may receive a pilot signal or the like, which may be a wireless signal output from sensor devices installed in a space such as the RF device 300. The controller 340 may apply a time reversal method to the pilot signal to determine a position of a sensor device that transmitted the pilot signal, a distance to the sensor device, or the like, and may control the signal transmitter 310 based thereon.

The signal receiver 320 may receive a data signal transmitted by the sensor device in addition to the pilot signal. The data signal may include detection data generated by collecting surrounding environmental data from a plurality of detectors included in the sensor device, such as a temperature, an air pressure, or a dust concentration of a surrounding space in which the sensor device is installed, or a temperature of plasma formed in the surrounding space, intensity of light emitted from the plasma, or the like. In this case, the controller 340 may control processing devices included in the production line along with the RF device, based on the detection data.

The power supplier 330 may supply a power supply voltage necessary for operation of the signal transmitter 310, the signal receiver 320, the controller 340, or the like. When the RF device 300 is fixedly installed as in an embodiment illustrated in FIG. 1, the power supplier 330 may be implemented without a battery, and may supply the power supply voltage to the signal transmitter 310, the signal receiver 320, and the controller 340.

When the RF device 300 should be implemented in a mobile manner as in embodiment illustrated in FIG. 2, the power supplier 330 may include a storage circuit for supplying a power supply voltage to the signal transmitter 310, the signal receiver 320, and the controller 340 during movement thereof, and a charging circuit for charging the storage circuit. When the RF device 300 needs to be moved, the RF device 300 may move and transmit the RF signal in a state in which the storage circuit is charged with energy.

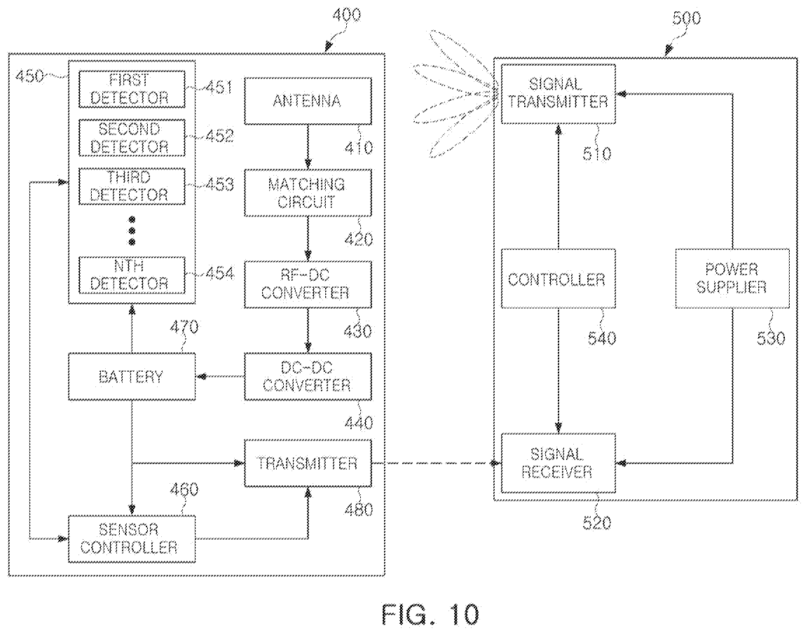

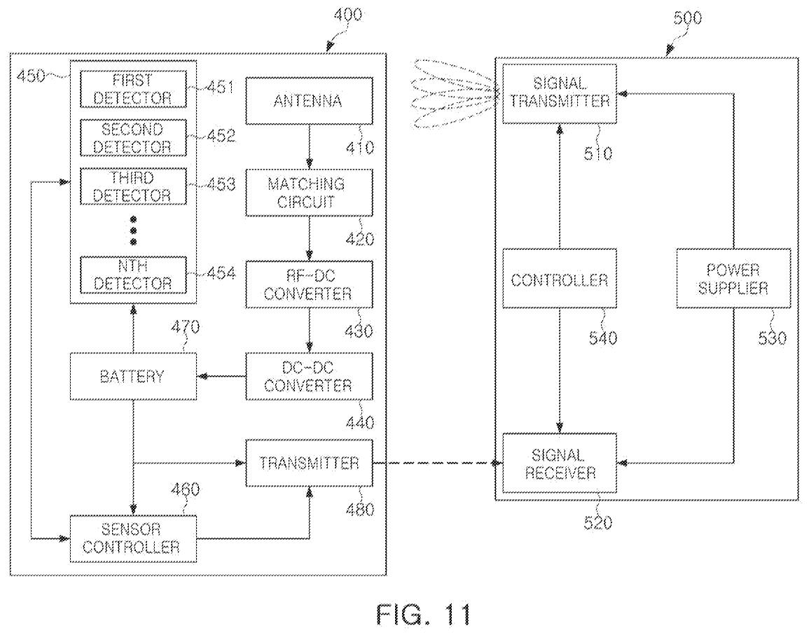

FIGS. 10 to 12 are views illustrating an operation of a system according to an embodiment.

First, referring to FIGS. 10 and 11, a system according to an embodiment may include a sensor device 400 and an RF device 500. The sensor device 400 may include an antenna 410, a matching circuit 420, an RF-DC converter 430, a DC-DC converter 440, a plurality of detectors 450 (e.g., detectors 451 to 454), a sensor controller 460, a battery 470, a transmitter 480, and the like. The RF device 500 may include a signal transmitter 510, a signal receiver 520, a power supplier 530, a controller 540, and the like.

When the sensor device 400 and the RF device 500 are respectively inserted into a production line in which the system is implemented, the RF device 500 may transmit an RF signal. The signal transmitter 510 may transmit the RF signal with an intensity and transmission direction according to an initial setting, and the sensor device 400 may charge the battery 470 using the RF signal transmitted by the RF device 500.

For example, the antenna 410 implemented as a patch antenna, a dipole antenna, a monopole antenna, or the like may convert the RF signal into an alternating current voltage, and may transmit the same to the RF-DC converter 430 through the matching circuit 420. The RF-DC converter 430 may convert the alternating current voltage into a direct current voltage, and the DC-DC converter 440 may charge the battery 470 by adjusting a level of the direct current voltage.

When the transmission direction or the intensity of the RF signal is not appropriately set, a charging speed of the battery 470 using the RF signal may be excessively slow. In an embodiment, when the charging speed of the battery 470 is determined to be too slow, or the like, the transmitter 480 may transmit a wireless signal.

The wireless signal transmitted by the transmitter 480 may proceed directly to the signal receiver 520, or may be reflected at least once from a surrounding wall, other equipment, or the like, and may then proceed to the signal receiver 520. Therefore, the controller 540 of the RF device 500 may determine a position of the sensor device 400 transmitting the wireless signal, a distance to the sensor device 400, or the like, using a time reversal method. Based on the position of the sensor device 400, the distance to the sensor device 400, or the like, the controller 540 may adjust a direction in which the signal transmitter 510 transmits the RF signal, intensity of the RF signal, or the like, as illustrated in FIG. 11, to improve charging efficiency of the sensor device 400.

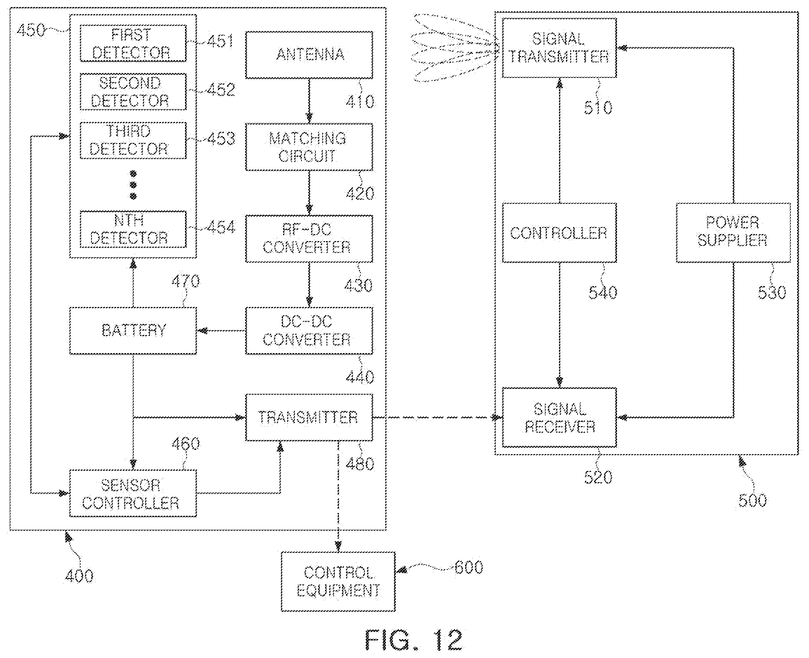

Referring to FIG. 12, a system according to an embodiment may further include control equipment 600. The control equipment 600 may receive a data signal including detection data generated by a plurality of detectors 450 from a transmitter 480. The control equipment 600 may be implemented as separate equipment from an RF device 500, and may control processing devices included in the system, together with a sensor device 400 and the RF device 500. For example, the control equipment 600 may control a temperature, an atmospheric pressure, an air circulation, or the like of a space in which a production line including the sensor device 400, the RF device 500, and the processing devices is implemented, based on the detection data generated by the plurality of detectors 450.

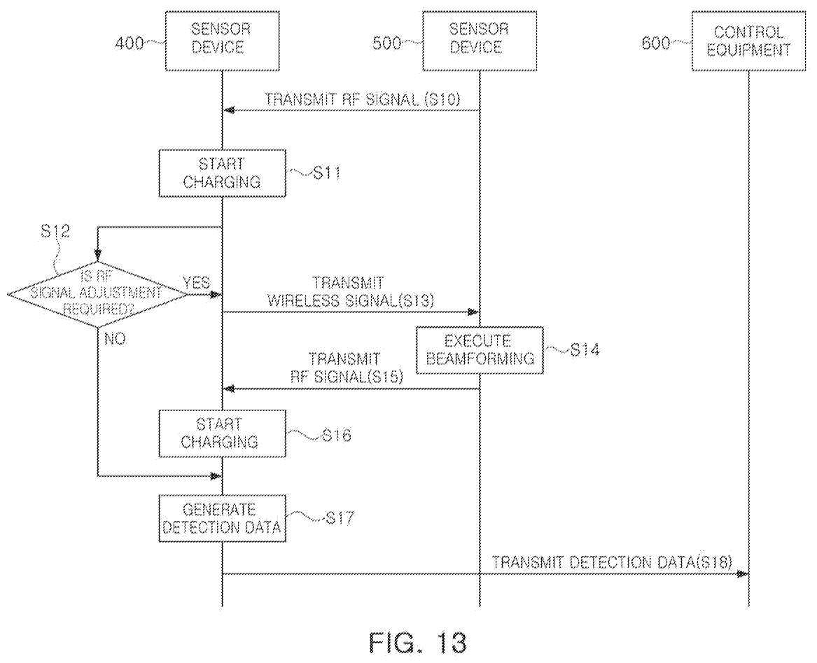

FIG. 13 is a view illustrating an operation of a system according to an embodiment.

Referring to FIG. 13, a system according to an embodiment may include a sensor device 400, an RF device 500, control equipment 600, and the like. The sensor device 400 may receive an RF signal transmitted by the RF device 500 (S10). The sensor device 400 may start an operation of charging a battery using the RF signal (S11).

While charging is in progress, the sensor device 400 may determine whether adjustment of the RF signal is needed (S12). For example, when a charging speed is too slow or an output voltage of the battery 470 is not stable, the sensor device 400 may determine that the adjustment of the RF signal is needed. When it is determined that the adjustment of the RF signal is needed, the sensor device 400 may transmit a wireless signal through a transmitter 480 (S13).

The wireless signal may be transmitted to the RF device 500, and the RF device 500 may determine a position of the sensor device 400 transmitting the wireless signal, a distance to the sensor device 400, or the like, using a time reversal method. The RF device 500 may execute a beamforming operation according to a determination result (S14) and transmit the RF signal again (S15). A transmission direction and intensity of the RF signal may be changed by the beamforming operation in operation S14.

The sensor device 400 may start an operation of charging again using the RF signal of which transmission direction and intensity have been adjusted (S16), and a plurality of detectors 450 may generate detect data using a power supply voltage output from the battery 470 may be created (S17). The sensor device 400 may transmit the detection data to the control equipment 600 through the transmitter 480 (S18), and the control equipment 600 may refer to the detection data, to maintain an optimized environment of a space in which the system is implemented, for example, a clean room environment. Depending on frequency of a signal transmitting the detection data, the sensor device 400 may transmit a data signal including the detection data to the control equipment 600, using an antenna receiving the RF signal.

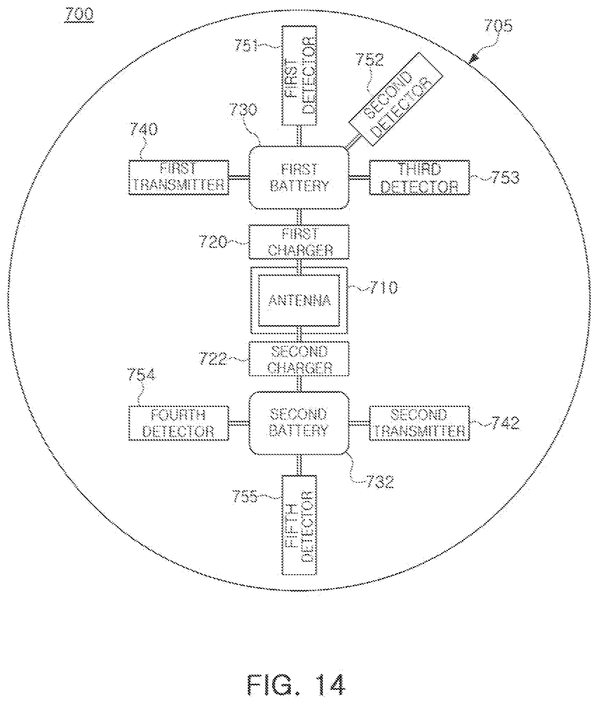

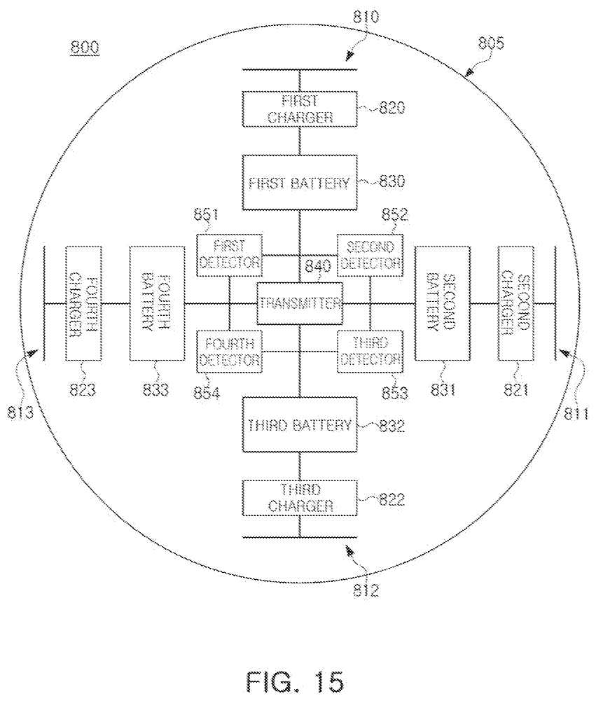

A sensor device 400 according to an embodiment may not only collect environmental data of an internal space in which the system is installed, but also be directly inserted into the semiconductor processing devices in which the semiconductor process is performed. In this case, the sensor device 400 may have a shape that may be automatically inserted into the semiconductor processing devices, for example, a wafer shape. The sensor device 400 inserted into the semiconductor processing devices may collect data necessary for analyzing a state of plasma formed to proceed with the semiconductor processing. Hereinafter, it will be described in more detail with reference to FIGS. 14 and 15.

FIGS. 14 and 15 are views illustrating a sensor device according to an embodiment.

First, referring to FIG. 14, a sensor device 700 according to an embodiment may include a case 705, an antenna 710, first and second chargers 720 and 722, first and second batteries 730 and 732, first and second transmitters 740 and 742, a plurality of detectors 751 to 755, and the like, stored in the case 705. In an embodiment illustrated in FIG. 14, the case 705 may have a wafer shape to be inserted into a semiconductor processing device, an FOUP, or the like, performing a semiconductor process.

In an embodiment illustrated in FIG. 14, the antenna 710 may be a patch antenna, and may be disposed in a region close to a center of the case 705. For example, the antenna 710 may be disposed to overlap the center of the case 705 in a direction, perpendicular to an upper surface of the case 705.

A first charger 720 and a second charger 722 may be connected to both sides of the antenna 710, and the first charger 720 and the second charger 722 may include a matching circuit, an RF-DC converter, a DC-DC converter, and the like, respectively. A first battery 730 may be charged by voltage output by the first charger 720, and a second battery 732 may be charged by voltage output by the second charger 722.

The first battery 730 may supply a power supply voltage to a first transmitter 740 and first to third detectors 751 to 753. The second battery 732 may supply a power supply voltage to a second transmitter 742 and fourth and fifth detectors 754 and 755. Each of the first transmitter 740 and the second transmitter 742 may transmit a wireless signal such that an external RF device may determine a position of the sensor device 700. For example, such that the RF device may accurately determine a position of the sensor device 700, a direction in which the first transmitter 740 transmits the wireless signal may be different from a direction in which the second transmitter 742 transmits the wireless signal.

In the embodiment of FIG. 14, it is illustrated that a single sensor device 700 includes a plurality of batteries 730 and 732 and a plurality of chargers 720 and 722, and a single antenna 710 converts an RF signal into an alternating voltage, but the disclosure is not necessarily limited thereto. For example, the sensor device 700 may include only one battery and one charger.

Next, referring to FIG. 15, a sensor device 800 according to an embodiment may include a case 805, antennas 810 to 813, first to fourth chargers 820 to 823, first to fourth batteries 830 to 833, a transmitter 840, a plurality of detectors 851 to 854, and the like, stored in the case 805. The number of antennas 810 to 813, chargers 820 to 823, batteries 830 to 833, and detectors 851 to 854 may vary depending on an embodiment.

In an embodiment illustrated in FIG. 15, first to fourth antennas 810 to 813 may be a monopole antenna or a dipole antenna including a line pattern, respectively. Each of the first to fourth antennas 810 to 813 may be disposed adjacent to an edge of the case 805, as illustrated in FIG. 15. At least one of the first to fourth antennas 810 to 813 may have a pattern shape that may be curved at least twice or more, rather than a straight line. A first charger 820 may charge a first battery 830 using an alternating current voltage generated by the first antenna 810 from an RF signal. A second charger 821 may charge a second battery 831 using an alternating current voltage generated by the second antenna 811 from the RF signal. A third battery 832 may be charged by a third charger 822, and a fourth battery 833 may be charged by a fourth charger 823.

In an embodiment illustrated in FIG. 15, the first to fourth antennas 810 to 813 may be installed at different positions in the case 805. Therefore, even when a position of the RF device transmitting the RF signal changes, the sensor device 800 may stably charge the batteries 830 to 833 to supply a power supply voltage required for operations of the transmitter 840 and the plurality of detectors 851 to 854.

Except for arrangement of which first to fourth antennas 810 to 813 are arranged close to the edge of the case 805, configurations and arrangement of the chargers 820 to 823, the batteries 830 to 833, the transmitters 840, and the plurality of detectors 851 to 854 may vary in various manners. For example, the number of batteries 830 to 833 may be smaller than the number of chargers 820 to 823.

In embodiments described with reference to FIGS. 14 and 15, the sensor devices 700 and 800 may be inserted into semiconductor processing devices in which a semiconductor process is actually performed. When plasma is generated in the semiconductor processing devices in a state in which the sensor devices 700 and 800 are inserted, the plurality of detectors 751 to 755 and 851 to 854 may detect a temperature of plasma, intensity of light emitted from the plasma, or the like. The plurality of detectors 751 to 755 and 851 to 854 may be implemented as a temperature sensor, a light detector detecting intensity of light, or the like.

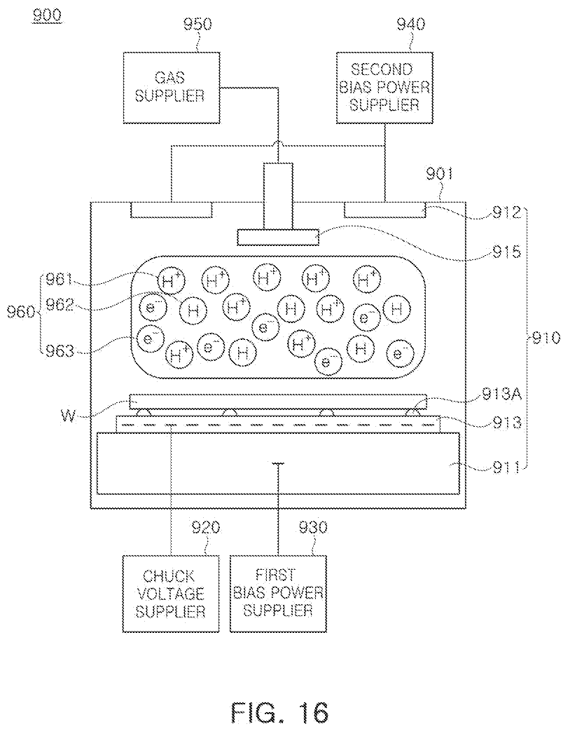

FIG. 16 is a view illustrating a semiconductor processing device into which a different sensor device may be inserted according to an embodiment.

Referring to FIG. 16, a semiconductor processing device 900 according to an embodiment may be a device that performs a semiconductor process using plasma. The semiconductor processing device 900 may include a chamber 910, a chuck voltage supplier 920, a first bias power supplier 930, a second bias power supplier 940, a gas supplier 950, and the like.

The chamber 910 may include a housing 901, a first bias electrode 911, a second bias electrode 912, an electrostatic chuck 913, a gas flow path 915, and the like. A sensor device for analyzing characteristics of plasma 960 or a process object to be processed for a semiconductor process may be seated on the electrostatic chuck 913. In the embodiment of FIG. 16, the process object is illustrated as a wafer W, but the process object may be changed as a display mother substrate, a mask, or the like.

As illustrated in FIG. 16, a plurality of protrusions 913A having a protrusion shape may be formed on an upper surface of the electrostatic chuck 913. The wafer W may be seated on the protrusions 913A, and thus a space may be formed between the upper surface of the electrostatic chuck 913 and the wafer W. For example, the space between the upper surface of the electrostatic chuck 913 and the wafer W may be filled with helium gas or the like for the purpose of cooling the wafer W.

In an embodiment, the wafer W may be fixed on the electrostatic chuck 913 by Coulomb force generated from a chuck voltage supplied to the electrostatic chuck 913 by the chuck voltage supplier 920. For example, the chuck voltage supplier 920 may supply the chuck voltage as a constant voltage to the electrostatic chuck 913, and the chuck voltage may have a magnitude of hundreds to thousands of volts.

To proceed with the semiconductor process, air may be removed from an internal space of the chamber 910, to form an environment close to a vacuum and having a very low atmospheric pressure, and a reaction gas may be introduced through the gas flow path 915. The first bias power supplier 930 may supply a first bias power to the first bias electrode 911 located below the electrostatic chuck 913, and the second bias power supplier 940 may supply a second bias power to the second bias electrode 912 located on the electrostatic chuck 913. Each of the first bias power supplier 930 and the second bias power supplier 940 may include an RF power source for supplying a bias power.

The plasma 960 containing an ion 961, a radical 962, an electron 963, and the like of the reaction gas may be generated in a space above the electrostatic chuck 913 by the first bias power and the second bias power. For example, when the semiconductor processing device 900 is etching equipment, the ion 961, the radical 962, the electron 963, and the like of the reaction gas may accelerate to the wafer W by the first bias power supplied by the first bias power supplier 930 to the first bias electrode 911. At least a portion of a semiconductor substrate or layers included in the wafer W may be dry-etched by the ion 961, the radical 962, the electron 963, and the like of the reactive gas.

Light may be emitted in a process of stabilizing a particle such as the ion 961 or the like in the plasma 960, and a wavelength band of the light emitted at this time may vary depending on a chemical species. Therefore, intensity of the light emitted from the plasma 960 may be detected in a predetermined wavelength band to detect characteristics such as a density, a thickness, or the like of the plasma.

In an embodiment, instead of the wafer W on which an etching process, a deposition process, or the like using the plasma 960 is performed, a sensor device, which is separately manufactured, may be disposed on the electrostatic chuck 913, and characteristics such as temperature distribution, a density, or the like of the plasma 960 may be analyzed using detection data generated by the sensor device may be performed. The sensor device may measure intensity of the light emitted by the plasma 960, a temperature of the plasma 960, or the like.

The sensor device may include a plurality of detectors that measure the intensity of the light emitted from the plasma 960, the temperature of the plasma 960, or the like, and a power supply voltage required for an operation of the plurality of detectors may be supplied by a battery while the sensor device is inserted into the semiconductor processing device 900. The sensor device may be transported to the semiconductor processing devices 900 while stored in a FOUP, or the like., and the battery may be charged using an RF signal transmitted by an external RF device while stored in a FOUP or the like.

The detection data generated by the sensor device may be used to control the semiconductor processing device 900. For example, control equipment controlling the semiconductor processing device 900 may adjust a gap between the first bias electrode 911 and the second bias electrode 912 such that the plasma 960 is uniformly formed on the wafer W based on the detection data received from the sensor device. Therefore, yield of the semiconductor process performed by the plasma 960 in the semiconductor processing device 900 may be improved.

According to an embodiment, a sensor device may produce a power supply voltage using an RF signal emitted by an external RF device, and may operate using this power supply voltage. The sensor device may be inserted into a semiconductor processing device to collect detection data for determining internal environment of the semiconductor processing device, or may be disposed in a space in which the semiconductor processing device is installed, to collect detection data for determining surrounding environment. The RF device outputting the RF signal charging the sensor device may be installed in a space such as the semiconductor processing devices, and the sensor device may be thus continuously operated in a space in which the system is installed, without a separate charging operation for the sensor device.

Various advantages and effects of the present disclosure are not limited to the above-described content, and may be more easily understood through description of specific embodiments of the present disclosure.

While example embodiments have been illustrated and described above, it will be apparent to those skilled in the art that modifications and variations could be made without departing from the scope of the present disclosure as defined by the appended claims.

What is claimed is:

1. A system comprising:
a radio frequency (RF) device configured to output an RF signal; and
at least one sensor device configured to generate a power supply voltage using the RF signal,
wherein the at least one sensor device is configured to operate on the power supply voltage,
wherein the at least one sensor device comprises:
a case;
a plurality of detectors disposed in the case, wherein the plurality of detectors are configured to operate on the power supply voltage, to collect environmental data of a space in which the at least one sensor device is inserted, and to generate detection data;
a battery configured to supply the power supply voltage; and
a charger configured to charge the battery, and
wherein the charger comprises an antenna disposed in the case and configured to receive RF power from an external source, an RF-DC converter configured to convert an alternating current voltage corresponding to the RF power into a direct current voltage, a matching circuit connected between the antenna and the RF-DC converter, and a DC-DC converter configured to adjust a level of the direct current voltage and to charge the battery.

2. The system of claim 1,
wherein the at least one sensor device further comprises a transmitter configured to transmit a wireless signal to the RF device, and
wherein the RF device is configured to, based on the wireless signal:
determine a position of the at least one sensor device and a distance to the at least one sensor device, and
adjust an intensity of the RF signal and a transmission direction of the RF signal.

3. The system of claim 2, wherein the wireless signal comprises a beacon signal.

4. The system of claim 2, wherein the RF device is configured to determine the position of the at least one sensor device and the distance to the at least one sensor device in a time reversal manner.

5. The system of claim 2, further comprising control equipment,
wherein the control equipment is configured to:
receive the detection data from the at least one sensor device, and
analyze an environment of the space, and
wherein the transmitter is further configured to transmit the detection data to the control equipment.

6. The system of claim 5, wherein the control equipment and the RF device are implemented as a single device.

7. The system of claim 5, further comprising:
a plurality of sensor devices including the at least one sensor device, wherein the plurality of sensor devices are disposed in different positions in the space,
wherein each of the plurality of sensor devices is configured to transmit the detection data to the control equipment.

8. The system of claim 1, wherein the RF device comprises a plurality of RF devices including the RF device, wherein the plurality of RF devices are fixedly installed in different positions in the space.

9. The system of claim 1,
wherein the RF device is movably installed in the space, and
wherein the RF device comprises:
a storage circuit configured to temporarily store power required to generate the RF signal; and
a charging circuit configured to charge the storage circuit.

10. A sensor device comprising:
a case;
an antenna disposed in the case and configured to receive a radio frequency (RF) signal transmitted by an RF device;
a matching circuit connected to the antenna and configured to output an alternating current voltage;
an RF-DC converter configured to convert the alternating current voltage into a direct current voltage;
a DC-DC converter configured to adjust a level of the direct current voltage to generate a power supply voltage;
a plurality of detectors configured to:
operate using the power supply voltage,
collect environmental data in a space outside the case, and
generate detection data; and
a transmitter configured to output a wireless signal configured to be recognized by the RF device.

11. The sensor device of claim 10, wherein the case comprises a wafer shape.

12. The sensor device of claim 11, wherein the detection data indicates at least one characteristic of plasma formed in the space outside the case.

13. The sensor device of claim 10, wherein the antenna comprises a patch antenna, and wherein the antenna is arranged to overlap a center of the case in a direction perpendicular to an upper surface of the case.

14. The sensor device of claim 10, wherein the antenna comprises a dipole antenna or a monopole antenna, and wherein the antenna is disposed closer to an edge of the case than a center of the case.

15. The sensor device of claim 10,
wherein the plurality of detectors generate the detection data in a predetermined sensing cycle, and
wherein the predetermined sensing cycle is longer than a time period required for the antenna, the RF-DC converter, and the DC-DC converter to generate the power supply voltage from the RF signal.

16. The sensor device of claim 10,
wherein at least one of the plurality of detectors collects second environmental data different from the environmental data collected by another detector of the plurality of detectors, and
wherein the at least one of the plurality of detectors generates the detection data based on the second environmental data.

17. The sensor device of claim 10, wherein the transmitter is configured to transmit the wireless signal through the antenna.

18. The sensor device of claim 10, wherein an output voltage of the DC-DC converter is directly supplied to the plurality of detectors and to the transmitter.

19. The sensor device of claim 10, further comprising a battery,
wherein the battery is configured to be charged by an output voltage of the DC-DC converter, and to supply the power supply voltage to the plurality of detectors and to the transmitter.

20. A system comprising:
a plurality of radio frequency (RF) devices, each installed in a different position and each transmitting an RF signal; and
a plurality of sensor devices disposed in a space in which the plurality of RF devices are installed,
wherein each of the plurality of sensor devices is configured to:
generate a power supply voltage using the RF signal transmitted by at least one of the plurality of RF devices, and
operate based on the power supply voltage, and
wherein each of the plurality of sensor devices comprises a transmitter configured to transmit a wireless signal configured to be recognized by each of the plurality of RF devices.
